(19) United States
(12) Patent Application Publication
(10) Pub. No.: US 2010/0140599 A1
(43) Pub. Date: Jun. 10, 2010

(54) SEMICONDUCTOR DEVICE, METHOD FOR MANUFACTURING SEMICONDUCTOR DEVICE, AND DISPLAY

(75) Inventors: Koki Yano, Chiba (JP); Hajime Nakanotani, Fukuoka (JP); Chihaya Adachi, Fukuoka (JP)

Correspondence Address: MILLEN, WHITE, ZELANO & BRANIGAN, P.C., 2200 CLARENDON BLVD., SUITE 1400, ARLINGTON, VA, 22201, US

(73) Assignees: KYUSHU UNIVERSITY, Fukuoka-shi, Fukuoka (JP); IDEMITSU KOSANCO., LTD., Tokyo (JP)

(21) Appl. No.: 12/593,030

(22) PCT Filed: Mar. 26, 2008
(86) PCT No.: PCT/JP2008/055633

§ 371 Date: Feb. 18, 2010

(30) Foreign Application Priority Data
Mar. 26, 2007 (JP) 2007-078998

(51) Int. Cl. H01L 51/52; H01L 51/56

(52) U.S. Cl. 257/40; 438/46; 257/43; 257/52; 257/49; 257/103; 438/104; 257/E51.022; 438/99

(57) ABSTRACT

A semiconductor device includes an organic semiconductor layer 10 and an oxide semiconductor layer 11, and emits light.

### TECHNICAL FIELD

The invention relates to a semiconductor device using an organic substance and emitting light, a method of producing the semiconductor device and a display apparatus using the semiconductor device.

### BACKGROUND ART

Recently, organic semiconductors using organic substances have gathered attention as materials used for semiconductors.

In general, such organic substances used for the organic semiconductors have advantages such that they can be easily formed into a film by using a simple film-forming method such as spin coating or vacuum deposition, and that the temperature during the production process thereof can be lowered in comparison with the conventional semiconductor devices using amorphous or polycrystalline silicon. Such lowering process temperature allows to form a film on a plastic substrate having lower heat resistance, to decrease the display weight and costs, and to give various applications having the advantage of flexibility of the plastic substrate, thereby many effects being expected.

Conventional semiconductor devices using organic substances as an organic semiconductor have been known from the technique disclosed in Patent Document 1, for example.

Patent Document 1 discloses the semiconductor device as the technology used for an organic electroluminescence device (organic EL devices). Such organic EL devices have a light-emitting part composed of an organic semiconductor layer, an electron-injecting electrode which injects electrons to the light-emitting part, and a hole-injecting electrode which injects holes to the organic semiconductor layer.

Light emission is generated due to recombination of electrons from the electron-injecting electrode and holes from the hole-injecting electrode.

Patent Document 2 discloses the technology of a semiconductor device used for display apparatuses and image apparatuses. The semiconductor device has a light-emitting part in which an organic semiconductor layer having n-type properties and an organic semiconductor layer having p-type properties are combined, and which exhibits bipolar properties.

Patent Document 3 discloses the technology of a semiconductor device having a light-emitting part which is composed of carbon nano tube or boron nitride nano tube and has bipolar properties.

Such a semiconductor device is a self-luminous device different from liquid crystal devices and has advantages such as no viewing angle dependency.

In the semiconductor device, direct-current electricity running through the light-emitting part is controlled by a transistor or the like, in order to control luminance of the light-emitting part.

Further, Patent Documents 2 and 3 disclose the technology of a light-emitting part that itself functions as a transistor, called an organic light-emitting transistor because when a transistor is provided in addition to the light-emitting part in a semiconductor apparatus, the production process becomes complicated, or the open area ratio decreases.

[Patent Document 1] JP-A-H05-315078

[Patent Document 2] JP-A-2005-209455

[Patent Document 3] JP-A-2006-501654

Incidentally, to increase luminous efficiency of the light-emitting part of the semiconductor device and to obtain good functions of the transistor, it is necessary to adequately set the balance of carriers (holes and electrons) injected to the light-emitting part.

However, in such a semiconductor device, it is difficult to adequately set both of the carriers injected and process yield decreases because the light-emitting part is made only of organic substances. Hence, such a semiconductor device has disadvantage of low production efficiency.

The invention was made in view of the above-mentioned problems, and an object of the invention is to provide a semiconductor device, a method of producing the semiconductor device and a display apparatus using the semiconductor device, wherein in the semiconductor device, an organic substance is used as an organic semiconductor, thereby reducing costs for production thereof, and the appropriate balance of carriers to be injected can be easily set so that the production efficiency increases.

### DISCLOSURE OF THE PRESENT INVENTION

To attain the above-mentioned object, the semiconductor device of the invention comprises an organic semiconductor layer and an oxide semiconductor layer, and emits light.

The light emission is preferably caused by recombination of holes and electrons.

The semiconductor device is preferably a transistor which has bipolar properties of n-type and p-type.

According to the semiconductor device, the light-emitting part comprises the organic semiconductor layer made of an organic substance and the oxide semiconductor layer made of an oxide in combination, thereby it being easy to adequately set balance of both of the carriers (holes and electrons) to be injected and the process yield being better, in comparison with a semiconductor device of which the light-emitting part is composed of an organic substance only whereby the production efficiency can be improved.

The light-emitting part can make the balance of carriers to be injected to be good. As a result, it is easy to increase luminous efficiency. Further, the transistor properties can be easily improved.

The oxide semiconductor layer is preferably made of an n-type nondegenerate oxide and preferably has an electron carrier concentration of less than 10¹⁸/cm³.

The oxide semiconductor layer is formed of an amorphous oxide containing at least one of In, Zn, Sn and Ga.

The oxide semiconductor layer is preferably formed of one of an amorphous oxide containing In, Ga and Zn, an amorphous oxide containing Sn, Zn and Ga, an amorphous oxide containing In and Zn, an amorphous oxide containing In and Sn, an amorphous oxide containing In and Ga, and an amorphous oxide containing Zn and Sn.

The oxide semiconductor layer is preferably formed of a polycrystalline oxide containing one of In, Zn, Sn and Ga.

The oxide semiconductor layer is preferably formed of a polycrystalline oxide containing In and a positive divalent element.

The oxide semiconductor layer preferably has a multilayered structure in which plural kinds of layered oxides are stacked, and among said multilayered structure, the material of the layered oxide nearest to the organic semiconductor layer preferably has the work function larger than the work function of the other layered oxide layer.

By the above-mentioned constitution of the semiconductor device, the carrier concentration to be injected to the oxide semiconductor layer and carrier mobility can be easily adjusted, thereby the process yield becoming good. As a result, the production efficiency can be increased. Further, it can be expected that the luminous efficiency and transistor functions increase.

The organic semiconductor layer is preferably formed of an organic substance having p-type characteristics, an organic substance having bipolar properties or an organic substance having n-type properties; or a multilayered body or a mixture of two or more kinds thereof.

By the above-mentioned constitution of the semiconductor device, carrier concentration to be injected to the organic semiconductor layer and carrier mobility can be easily adjusted, thereby the process yield becoming good. As a result, the production efficiency can be increased. Further, it can be expected that the luminous efficiency and transistor functions increase.

The organic semiconductor layer is preferably formed of an organic substance which emits light due to recombination of holes and electrons.

By this, light emission can be generated in the organic semiconductor layer.

The organic semiconductor layer and the oxide semiconductor layer are preferably in contact with each other.

The organic semiconductor layer and the oxide semiconductor layer preferably form a light-emitting part.

It is preferred that a first electrode is provided on the light-emitting part through an insulator layer, a second electrode is provided in contact with the light-emitting part and interspatially from said first electrode, and a third electrode is provided in contact with the light-emitting part and interspatially from said first and second electrodes.

In the semiconductor device, the first electrode is used as a gate electrode, the electrode having lower voltage among the second and third electrodes is used as an electron-injecting electrode, and the electrode having higher voltage among them is used as a hole-injecting electrode. When applying voltage to the electron-injecting electrode and the hole-injecting electrode, electrons and holes are injected to the light-emitting part. Then, electrons and holes injected recombine with each other within the light-emitting part.

Electrons and holes recombine with each other within the light-emitting part 1 to generate energy due to recombination. The organic substance molecules or oxide molecules residing in the vicinity of the position where recombination occurred are excited from the ground state, and release energy which is the difference in energy between the excited state and the ground state, as light emission at the time when they return to the ground state.

By controlling voltage of the gate electrode or the like, the electric current which flows between the second electrode and the third electrode is controlled. According to this constitution, amounts of carriers (holes and electrons) to be injected to the light-emitting part are increased or decreased. By this, luminance of the light-emitting part can be controlled.

The organic semiconductor layer and the oxide semiconductor layer are preferably formed into a thin film.

A ratio of field-effect mobility μ(n) at n-type driving and field-effect mobility μ(p) at p-type driving [μ(n)/μ(p)] is preferably in a range of 10⁻⁵≦μ(n)/μ(p)≦10⁵.

The semiconductor device having the above-mentioned constitution has excellent luminance and transistor functions.

In order to attain the above-mentioned object, in the method of producing the semiconductor device of the invention, an oxide semiconductor layer is formed, said oxide semiconductor layer is placed in an environment in the presence of oxygen and/or ozone, and then an organic semiconductor layer is formed.

According to the production method having such a constitution, the oxide semiconductor layer can be placed under atmosphere in the presence of oxygen and subjected to surface cleaning or modification such as ozone treatment.

When the oxide semiconductor is placed in an environment in the presence of oxygen, polarized functional groups such as —OH groups increase due to operation of oxygen or ozone. As a result, an effect that injection properties of electrons and holes change can be expected.

This brings about increase the freedom of the production processes and makes practical application to be easier.

In order to attain the above-mentioned object, the display apparatus of the invention uses the above-mentioned semiconductor device.

By this, the display apparatus becomes simple in the structure since it uses the semiconductor device having light-emitting function and transistor function. As a result, the production process of the display apparatus can be simple and production efficiency can be improved.

According to the invention, carrier balance can be easily stabilized in comparison with the semiconductor device having an organic semiconductor layer made only of an organic substance, since the semiconductor device has the light-emitting part composed of the organic semiconductor layer and the oxide semiconductor layer. As a result, production efficiency can be improved.

### BRIEF DESCRIPTION OF THE DRAWINGS

FIG. 1A is a schematic cross-sectional view of the semiconductor device according to the first embodiment of the invention.

FIG. 1B is an enlarged cross-sectional view showing essential parts of the semiconductor device according to the first embodiment of the invention.

FIG. 2 is a schematic cross-sectional view of the semiconductor device according to the second embodiment of the invention.

FIG. 3 is a schematic cross-sectional view of the semiconductor device according to the third embodiment of the invention.

FIG. 4 is a schematic cross-sectional view of the semiconductor device according to the fourth embodiment of the invention.

FIG. 5 is a schematic cross-sectional view of the semiconductor device according to the fifth embodiment of the invention.

FIG. 6 is a schematic cross-sectional view of the semiconductor device according to the sixth embodiment of the invention.

FIG. 7 is a schematic cross-sectional view of the semiconductor device according to the seventh embodiment of the invention.

FIG. 8 is a schematic cross-sectional view of the semiconductor device according to the eighth embodiment of the invention.

FIG. 9 is a schematic cross-sectional view of a modification example of the semiconductor device according to the seventh embodiment of the invention.

FIG. 10 is a drawing showing the display apparatus according to one embodiment of the invention. (a) is a horizontal sectional view, and (b) is a drawing showing wiring among the first to the third electrodes from the view point in the direction of the arrow A in FIG. 10 (a).

FIG. 11 is a drawing showing the semiconductor device according to Example 1 of the invention. (a) is a drawing showing the concept of the status of carriers within the semiconductor device, and (b) is a graph showing the voltage difference between the electrodes.

FIG. 12 is a graph showing the relationship between the drain voltage and drain current in the semiconductor device of Example 1 of the invention.

FIG. 13 is a graph showing the relationship between the gate-source voltage and the drain-source current in the semiconductor device of Example 1 of the invention.

FIG. 14 is a graph showing the relationship between the drain-source voltage and the luminance of the semiconductor device of Example 1 of the invention.

FIG. 15 is a graph showing the electroluminescence spectrum together with the photoluminescence spectrum of tetracene in the semiconductor device of Example 1 of the invention.

FIG. 16(a) is a graph showing the relationship between the drain-source voltage and the luminance, (b) is a drawing showing the concept of status of carriers in the semiconductor device when the gate-source voltage is low (V_{GS}=−20V), and (c) is a drawing showing the concept of status of carriers in the semiconductor device when the gate-source voltage is high (V_{GS}=−80V), in the semiconductor device of Example 1 of the invention.

FIG. 17A is a graph showing the relationship between the drain voltage and the drain current in the semiconductor device of Example 2 of the invention.

FIG. 17B is a graph showing the relationship between the drain voltage and the luminance in the semiconductor device of Example 2 of the invention.

FIG. 18 is a drawing showing the relationship between the gate voltage and the drain current in the semiconductor device of Example 2 of the invention.

### BEST MODE FOR CARRYING OUT THE PRESENT INVENTION

Hereinafter, explanations will be given to embodiments of the semiconductor device, the method of producing the semiconductor device, and the display apparatus using the semiconductor device of the invention with reference to the drawings.

### First Embodiment

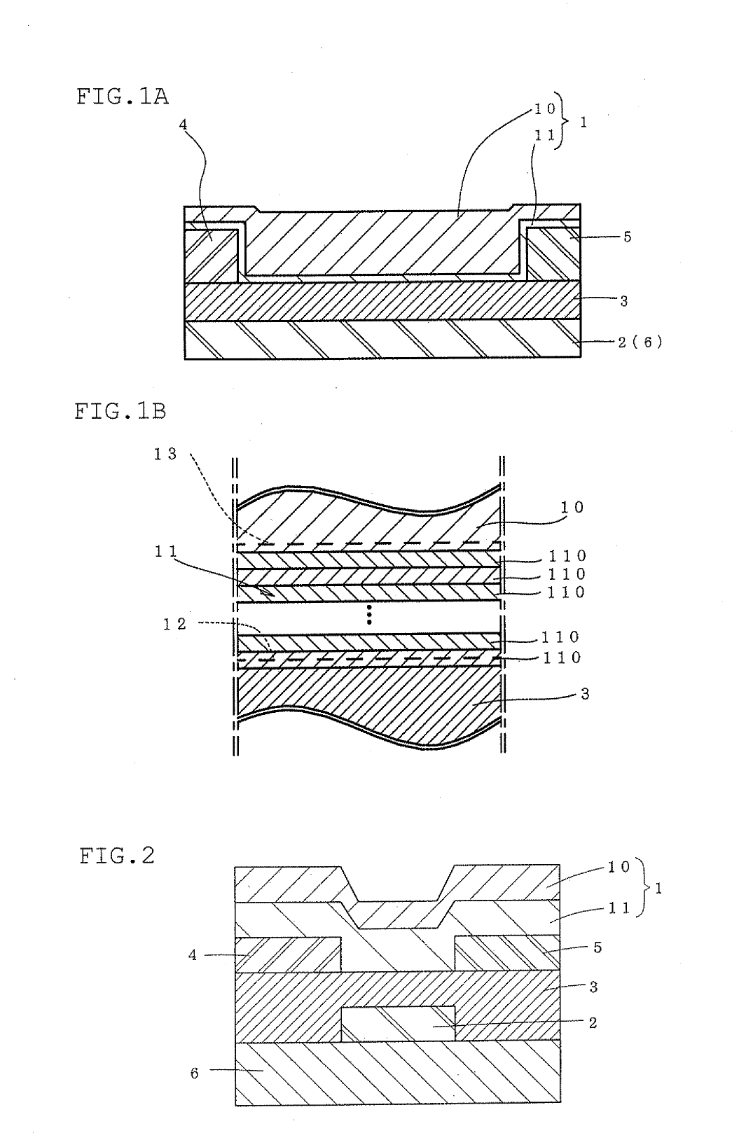

FIG. 1 is a schematic cross-sectional view of the semiconductor device according to the first embodiment of the invention.

As shown in FIG. 1A, the semiconductor device comprises an light-emitting part 1 formed from an organic semiconductor layer 10 and an oxide semiconductor layer 11, and emits light due to recombination of holes and electrons within the light-emitting part 1.

Specifically, light emission may be generated at the organic semiconductor layer 10, the oxide semiconductor layer 11 or both thereof, or the interface of the organic semiconductor layer 10 and the oxide semiconductor layer 11, as long as it is within the light-emitting part 1. Light emission is preferably generated at the organic semiconductor layer 10, or in the vicinity of the interface of the organic semiconductor layer 10 and the oxide semiconductor layer 11.

The semiconductor device of this embodiment comprises a light-emitting part 1 formed from an organic semiconductor layer 10 and an oxide semiconductor layer 11, a first electrode 2 provided on the light-emitting part 1 through an insulator layer 3, a second electrode 4 provided in contact with the light-emitting part 1 and interspatially from the first electrode 2, and a third electrode 5 provided in contact with the light-emitting part and interspatially from the first and second electrodes 2 and 4.

This semiconductor device is used as a light-emitting element, and layers in the state of thin films are stacked on a substrate 6.

In particular, the semiconductor device has the substrate 6 used as the first electrode 2, the insulator layer 3 formed on the substrate 6, the light-emitting part 1 formed on the insulator layer 3, and the second and third electrodes 4 and 5 provided between the insulator layer 3 and the light-emitting part 1 and interspatially from each other.

The light-emitting part 1 in the invention has bipolar properties of n-type and p-type and transistor functions.

The light-emitting part 1 has the organic semiconductor layer 10 made of an organic substance and the oxide semiconductor layer 11 made of an oxide, and the organic semiconductor layer 10 and the oxide semiconductor layer 11 are formed over from the second electrode 4 side to the third electrode 5 side. The organic semiconductor layer 10 and the oxide semiconductor layer 11 are in contact with each other.

The light-emitting part 1 is preferably constituted in a combination selected from the one wherein the whole organic semiconductor layer 10 has p-type properties and the whole oxide semiconductor layer 11 has n-type properties, the one wherein the whole organic semiconductor layer 10 has n-type properties and the whole oxide semiconductor layer 11 has p-type properties, and the one wherein the whole organic semiconductor layer 10 has bipolar properties and the whole oxide semiconductor layer 11 has p-type or n-type properties. Of these combinations, the light-emitting part 1 is preferably constituted in the one wherein the whole organic semiconductor layer 10 has p-type properties and the whole oxide semiconductor layer 11 has n-type properties. The reason therefor is that the band gap of an n-type oxide semiconductor is larger than the band gap of an n-type organic semiconductor.

The organic semiconductor layer 10 is made of an organic substance which emits light due to recombination of holes and electrons.

Further, the organic semiconductor layer 10 is made of an organic substance having p-type properties, an organic substance having bipolar properties or an organic substance having n-type properties; or a multilayered body or a mixture of two or more kinds thereof.

Specifically, the organic semiconductor layer 10 is made of an organic substance which emits light due to recombination of holes and electrons, and made of at least one selected from the group consisting of organic low-molecular compounds such as pentacene and oligothiphene; organic polymers such as polythiophene; metal complexes such as phthalocyanine; fullerenes such as C₆₀, C₈₂, a metal-containing fullerene (for example, dysprosium (Dy)-containing fullerene (Dy@C_{B2})); and carbon nano tubes.

Of the above-mentioned organic semiconductor layers 10, preferred is the one made of an organic substance having p-type properties or an organic substance having bipolar properties; or a multilayered body or a mixture thereof.

In particular, of the organic semiconductor layers 10, the one made of a multilayered body or a mixture of an organic substance having p-type properties, or an organic substance having p-type properties is more preferable. The reason therefor is that an organic substance having p-type properties does not undergo deterioration even when it contacts with atmosphere.

The organic substance having p-type properties for constituting the organic semiconductor layer 10 includes 1,4-bis(4-methylstyryl)benzene (4MSB) and 1,4-bis(2-methylstyryl)benzene (2MSB) (as to both compounds, see Japanese Journal of Applied Physics Vol. 45, No. 11, 2006, pp. L313-L315); pentacene, tetracene, anthracene, phthalocyanine, α-sexithiophene, α,ω-dihexyl-sexithiophene, oligophenylene, oligophenylenevinilene, dihexyl-anthradithiophene, bis(dithienothiophene), poly(3-hexylthiophene), poly(3-butylthiophene), poly(phenylenevinylene), poly(thienylenevinylene), polyacetylene, α,ω-dihexyl-quinquethiophene, TPD, α-NPD, m-MTDATA, TPAC, TCTA, and poly(vinylcarbazole).

The organic substance having n-type properties for constituting the organic semiconductor layer 10 includes C₆-PTC, C₈-PTC, C₁₂-PTC, C₁₃-PTC, Bu-PTC, F₇Bu-PTC*, Ph-PTC, F₅Ph-PTC*, PTCBI, PTCDI, Me-PTC, TCNQ and C₆₀ fullerene.

The organic substance having bipolar properties for constituting the organic semiconductor layer 10 includes pentacene, rubrene, copper phthalocyanine and tetracene, which have high purity.

The organic substance used for the organic semiconductor layer preferably has a fluorescent quantum yield of 1% or more, more preferably 5% or more, further preferably 10% or more, and particularly preferably 20% or more.

In this embodiment, a method of forming the organic semiconductor layer 10 includes chemical film-forming methods such as a spray method, a dip method and a CVD method, as well as physical film-forming methods such as a vacuum vapor deposition. Taking control properties of carrier density or improvement in the quality of film into consideration, the physical film-forming methods are preferable.

In this embodiment, the oxide semiconductor layer 11 is made of a nondegenerate oxide having n-type properties. This oxide semiconductor layer 11 is made into a transparent oxide semiconductor layer.

The oxide semiconductor layer 11 preferably has an electron carrier concentration of less than 10¹⁸/cm³, more preferably less than 10¹⁷/cm³, further preferably less than 5×10¹⁶/cm³, and particularly preferably less than 10¹⁶/cm³.

The lower limit of the electron carrier concentration is not limited but it is usually 10¹⁰/cm³ or more, and preferably 10¹²/cm³ or more. When the electron carrier concentration is 10¹⁸/cm³ or more, it may become difficult to balance the conductivity with the organic semiconductor and the bipolar properties may not be displayed.

This oxide semiconductor layer 11 is preferably formed of an amorphous oxide containing at least one selected from In, Zn, Sn and Ga. The oxide semiconductor layer 11 is formed of an amorphous oxide containing In, Ga Zn and Sn, an amorphous oxide containing In, Ga and Zn, an amorphous oxide containing Sn, Zn and Ga, an amorphous oxide containing In and Zn, an amorphous oxide containing in and Sn, an amorphous oxide containing In and Ga, or an amorphous oxide containing Zn and Sn. In, Sn, Zn and Ga have a relatively large s orbital, indicate good n-type semiconductor properties even when it becomes amorphous, and have good electron transporting property. As a result, it can be expected that it displays high semiconductor characteristics such as mobility.

Alternatively, the oxide semiconductor layer 11 is preferably formed of a polycrystalline oxide containing In, Zn, Sn or Ga, and more preferably formed of a polycrystalline oxide containing In and a positive divalent element. The carrier density of the polycrystalline oxide containing in, Zn, Sn or Ga can be controlled in the oxide partial pressure at the time of film formation and in oxidation treatment after film formation. In, Sn, Zn and Ga have a relatively large s orbital and display good n-type semiconductor properties. As a result, good electron-transporting properties and high semiconductor properties such as mobility can be expected. In particular, In has a larger s orbital, and it can be expected that little decrease of the electron-transporting property is brought about by scattering in grain boundary even when polycrystallized. Further, the carrier concentration can be relatively easily controlled to the desired concentration by changing the concentration of the positive bivalent element without treatment at a high temperature of 450° C. or higher.

This oxide semiconductor layer 11 is preferably formed of a polycrystalline compound containing In, Zn, Sn or Ga rather than an amorphous oxide containing In, Zn, Sn or Ga. The reason therefor is that control of electron carrier density (reduction) and high electron mobility are easily consistent with each other and high reliability is obtainable.

The positive bivalent element includes Zn, Be, Mg, Ca, Sr, Ba, Ti, V, Cr, Mn, Fe, Co, Ni, Pd, Pt, Cu, Ag, Cd, Hg, Sm, Eu and Yb. Of these, Zn, Mg, Mn, Co, Ni, Cu and Ca are preferable. Among them, more preferred are Zn, Mg, Cu, Ni, Co and Ca because the carrier concentration can be efficiently controlled. Cu and Ni are particularly preferable in view of the carrier-controlling effect by the addition thereof, and Zn and Mg are particularly preferable in view of the transmittance and the width of band gap. These positive bivalent elements may be used in combination within a range wherein the effects of this embodiment are not lost. Here, the positive bivalent element is an element which can be positive bivalent in the state of ion.

The oxide semiconductor layer 11 may contain an element or a compound other than indium oxide and an oxide of a positive bivalent element. However, it usually contains 50% by mass or more of indium oxide and the oxide of a positive bivalent element in total. If the content is less than 50% by mass, the effects may not be exhibited sufficiently such as decrease of the mobility. In order to make the effects sufficiently to exhibit, indium oxide and an the oxide of a positive bivalent element are preferably contained in an amount of 65% by mass or more in total, more preferably 80% by mass or more, further preferably 90% by mass or more, and particularly preferably 95% by mass or more. In order to make the effect of controlling carrier sufficiently to exhibit, the content of a positive tetravalent element such as Sn is preferably 3% by mass or less, more preferably 2% by mass or less, and particularly preferably 1% by mass or less. If the positive tetravalent element is contained, the carrier density may not be controlled to be low.

An atomic ratio [X/(X+In)] of indium [In] and a positive bivalent element [X] contained in the oxide semiconductor layer 11 can be 0.0001 to 0.5.

When the atomic ratio [X/(X+In)] is less than 0.0001 or the content of the positive bivalent element is smaller, the effects of this embodiment may not be exhibited so that the number of carriers can not be controlled.

On the other hand, when the atomic ratio [X/(X+In)] is more than 0.5 or the content of the positive bivalent element is excessive, the interface or surface may be likely to change its nature and to be unstable, the crystallization temperature may be high so that crystallization becomes difficult, the carrier concentration may increase, or the hall mobility may decrease. Further, a threshold voltage may vary at the time of driving the transistor, or driving may be unstable. To avoid the above-mentioned problems effectively, the atomic ratio [X/(X+In)] is preferably 0.0002 to 0.15, more preferably 0.0005 to 0.1, further preferably 0.001 to 0.09, and particularly preferably 0.005 to 0.08. Most preferred is 0.01 to 0.07.

In the invention, an oxide which indicates Halo pattern in the X-ray diffraction spectrum and no specific diffraction line is called as an amorphous oxide, while an oxide which indicates a specific diffraction line is called as a polycrystalline oxide.

The electron carrier concentration of the oxide according to the invention is indicated as a value determined at room temperature. The room temperature is 25° C., for example, and specifically, a certain temperature is optionally selected within a range of 0 to 40° C. The oxide according to the invention does not necessarily satisfy the electron carrier concentration of less than 10¹⁸/cm³ throughout a range of 0 to 40° C. For instance, it is sufficient that the carrier electron density is less than 10¹⁸/cm³ at 25° C.

By more decrease of the electron carrier concentration of 10¹⁷/cm³ or less, and more preferably 10¹⁶/cm³ or less, semiconductor devices having bipolar properties can be obtained in good yield.

The oxide semiconductor layer 11 is preferably formed of an oxide containing a lanthanoid element. Addition of the lanthanoid element to the oxide semiconductor layer can increase the work function of the oxide semiconductor layer 11.

The work function of the oxide semiconductor layer 11 is preferably 4.8 (eV) or more, more preferably 5.2 (eV) or more, and particularly preferably 5.6 (eV) or more.

The band gap of the oxide semiconductor layer 11 is preferably 2.5 (eV) or more, more preferably 2.8 (eV) or more, and particularly preferably 3.1 (eV) or more. When the band gap is less than 2.5 (eV), visible light may be absorbed in larger amount so that the transparency decreases, colorization occurs, or photo-deterioration is likely to occur.

The refractive index of the oxide semiconductor layer 11 is preferably 2.3 or less, more preferably 2.1 or less, and particularly preferably 2.0 or less. When the refractive index is higher than 2.3, reflectance may increase when it is stacked with the organic semiconductor layer 10.

As shown in FIG. 1B, the oxide semiconductor layer 11 may be formed in a multilayered structure in which plural kinds of layered oxides 110 are stacked. The transistor properties and light-emitting properties can be adjusted by adjusting the composition and the like of each layer of the layered oxides. In particular, by adjusting the work function of the oxide semiconductor layer in contact with the organic semiconductor layer 10, injection property of electrons or holes can be controlled to adjust and optimize the balance of p-type and n-type properties. Among the multilayered structure of the layered oxides 110, the material of the layered oxide 110 nearest to the organic semiconductor layer 10 has a work function larger than a work function of the other layered oxide 110.

In this embodiment, as the method of forming the oxide semiconductor layer 11, chemical film-forming methods such as a spray method, a dip method and the CVD method, as well as physical film-forming methods can be used.

As the method of forming the oxide semiconductor layer 11, physical film-forming methods are preferable in view of the controllability of the carrier density and improvement in the quality of the film.

The physical film-forming methods include sputtering method, vacuum deposition method, ion plating method and pulsed laser deposition method. Sputtering method having a high mass productivity is preferable for industrial application.

The sputtering method includes the DC sputtering method, the RF sputtering method, the AC sputtering method, the ECR sputtering method and the facing targets sputtering method. Of these, the DC sputtering method and the AC sputtering method are preferable because they have high industrial mass productivity and control the carrier concentration more easy than the RF sputtering method. The ECR sputtering method and the facing targets sputtering method, which easily control the quality of the film, are preferable, in order to control deterioration of the interface by film formation to control electric leakage and to improve the properties of the oxide semiconductor layer 11 such as an on-off ratio.

A distance between a substrate and a target during sputtering (S-T distance) is usually 150 mm or less, preferably 110 mm, and particularly preferably 80 mm or less.

When the S-T distance is short, the substrate is exposed to plasma during sputtering so that improvement in the quality of the film can be expected. When it is longer than 150 mm, the film-forming rate may delay thereby it being improper to the industrial application.

In the case where the sputtering method is employed, a sintered target containing oxygen may be used, and the reactive sputtering using a metal or alloy target while introducing a gas such as oxygen may be conducted.

In view of the reproducibility, the uniformity in a large area and the properties of a TFT produced, the sintered target containing oxygen is preferably used.

At the production of a sintered target, sintering is preferably carried out under reduction atmosphere. The bulk resistance of the sintered target is preferably 0.001 to 1000 mΩcm, and more preferably 0.01 to 100 mΩcm. The sintered density of the sintered target is usually 70%, preferably 85% or more, more preferably 95% or more, and particularly preferably 99% or more.

When the sputtering method is employed, the ultimate pressure is usually 5×10⁻² Pa or less. If the ultimate pressure is larger than 5×10⁻² Pa, a large amount of hydrogen atoms are supplied from H₂O and the like which are contained in atmospheric gas so that mobility may decrease. This is considered that the crystalline structure of indium oxide changes due to bonding of hydrogen atoms.

In order to effectively avoid these problems, the ultimate pressure is preferably 5×10⁻³ Pa or less, more preferably 5×10⁻⁴ Pa or less, more preferably 1×10⁻⁴ Pa or less, and particularly preferably 5×10⁻⁵ Pa or less.

The oxygen partial pressure in atmospheric gas is usually 40×10⁻³ Pa or less. When the oxygen partial pressure in atmospheric gas is higher than 40×10⁻³ Pa, the mobility may decrease or the carrier concentration may be unstable.

The reason therefor is guessed that when amount of oxygen in atmospheric gas during film formation is too large, amount of oxygen taken in the crystalline lattice may be larger to cause scattering, or oxygen may easily get off to bring about destabilization.

To effectively avoid these problems, the oxygen partial pressure in atmospheric gas is preferably 15×10⁻³ Pa or less, more preferably 7×10⁻³ Pa or less, and particularly preferably 1×10⁻³ Pa or less.

The concentration of water, H₂O, or hydrogen, H₂, in atmospheric gas is usually 1.2 vol % or less. When it is larger than 1.2 vol %, the hall mobility may decrease.

To effectively avoid such a problem, the concentration of water, H₂O, or hydrogen, H₂, in atmospheric gas is preferably 1.0 vol % or less, more preferably 0.1 vol % or less, and particularly preferably 0.01 vol % or less.

In such a film-forming process, in the case where the oxide semiconductor layer 11 is formed of a polycrystalline oxide, any one of a method of forming a polycrystalline film, or a method of making a film formed to be polycrystalline by a post-treatment or a method of increasing crystallinity of a film formed may be employed.

In the method of forming a polycrystalline film, physical film formation is usually carried out at a substrate temperature of 250 to 550° C. The substrate temperature is preferably 300 to 500° C., and more preferably 320 to 400° C. When it is 250° C. or lower, crystallinity may be lower so that the carrier density becomes higher. When it is 550° C. or higher, cost may be higher and the substrate may become deformed.

In the method wherein a film formed is crystallized in a post-treatment or wherein crystallinity of a film formed is increased, physical film formation is usually carried out at a substrate temperature of 250° C. or lower. When the substrate temperature is higher than 250° C., effect of the post-treatment does not exhibit sufficiently so that it may be difficult to control the carrier concentration to be low and the mobility to be high. To effectively avoid these problems, the substrate temperature is preferably 200° C. or lower, more preferably 150° C. or lower, further preferably 100° C. or lower, and particularly preferably 50° C. or lower.

The method of forming a film containing a crystalline substance is preferable because of its simple process. However, to obtain high semiconductor characteristics, the method wherein a film formed is crystallized in a post-treatment is preferable because of good crystallinity, smaller membrane stress and easy control of carriers.

Although a film may contain crystals before crystallization in the post-treatment, the method wherein an amorphous film is once formed and crystallized in the post-treatment is preferable because control of the crystallinity can be conducted easily to obtain a semiconductor film having good quality.

In the case where a film having a large area is formed by the sputtering method, in order to uniform the film quality, a method is preferably employed in which a folder immobilizing a substrate is rotated or an erosion area is enlarged by moving a magnet.

After completion of these film formation processes, the carrier concentration in the transparent oxide semiconductor layer 11 can be controlled by application of an oxidation treatment process or a crystallization process.

There is a method wherein the carrier concentration is controlled by controlling the concentration of a gas component such as oxygen during film formation. However, in such a method, the hall mobility may be lower. The reason therefor is guessed that the gas component introduced to control carriers is taken in the film to be a scattering factor.

When a polycrystalline film is used as the oxide semiconductor layer 11, it is preferred that an amorphous film is formed and then crystallized at the time of oxidation treatment. By this, low carrier concentration can be achieved while maintaining high hall mobility.

In the oxidation treatment process or the crystallization treatment, a film is usually heat-treated under conditions of 80 to 650° C. for 0.5 to 12000 minutes in the presence of oxygen or in the absence of oxygen. The oxidation treatment process or the crystallization treatment is preferably conducted in the presence of oxygen because it can be expected that decrease of oxygen deficit occurs simultaneously.

When temperature of the heat treatment is lower than 80° C., the effect of the treatment may not exhibit or the treatment may require too long time. When it is higher than 650° C., energy cost may increase, tact time may be longer, a threshold voltage of the transistor produced may be larger, or the substrate may deform. To effectively avoid these problems, the treatment temperature is preferably 120 to 500° C., more preferably 150 to 450° C., further preferably 180 to 350° C., and particularly preferably 200 to 300° C. The most preferred is 220 to 290° C.

When the heat treatment time is shorter than 0.5 minute, the time for conducting heat to the inside of a film is too short so that the treatment may be insufficient. When it is longer than 12000 minutes, a treatment apparatus to be used becomes larger in size so that it may not be used industrially, or a substrate may be damaged or deformed during the treatment. To effectively avoid these problems, the treatment time is preferably 1 to 600 minutes, more preferably 5 to 360 minutes, further preferably 15 to 240 minutes, and particularly preferably 30 to 120 minutes.

In the oxidation treatment process or the crystallization treatment, the heat treatment can be conducted with a lamp annealing apparatus (LA; Lamp Annealer), a rapid thermal annealing apparatus (RTA; Rapid Thermal Annealer) or a lesser annealing apparatus in the presence of oxygen or in the absence of oxygen. As the oxidation treatment process or the crystallization treatment, atmospheric plasma treatment, oxygen plasma treatment, ozone treatment or irradiation treatment such as ultraviolet radiation can also be applied. These treatment methods may be combined such that ultraviolet radiation is applied and ozone treatment is conducted while heating the substrate.

When heat treatment is conducted, the temperature of the film surface at the time of heat treatment is preferably higher than the substrate temperature at the time of film formation by 100 to 270° C. When the difference in temperature is smaller than 100° C., effects of the heat treatment may not be obtained. When it is larger than 270° C., the substrate may deform, or the interface of the semiconductor thin film may change in quality to deteriorate the semiconductor properties. To effectively avoid these problems, the temperature of the film surface at the time of heat treatment is preferably higher than the substrate temperature at the time of film formation by 130 to 240° C., and particularly preferably by 160 to 210° C.

The substrate 6 is formed of an inorganic substance or an organic substance.

Specifically, the substrate 6 formed of an inorganic substance includes a p-type monocrystal silicon substrate, a n-type monocrystal silicon substrate, a glass substrate and a quartz substrate to which boron (B), phosphorous (P), antimony (Sb), etc. are added as an impurity.

The substrate 6 formed of an organic substance includes plastic substrates such as polymethyl methacrylate, polyether sulfone and polycarbonates.

In this embodiment, the substrate 6 is also used as the first electrode 2. Hence, the substrate 6 is a silicon substrate, for example.

The insulator layer 3 may be made of, for example, an oxide such as SiO₂, Al₂O₃, Ta₂O₅, TiO₂, MgO, ZrO₂, CeO₂, K₂O, Li₂O, Na₂O, Rb₂O, Sc₂O₃, Y₂O₃, Hf₂O₃, CaHfO₃, PbTi₃, BaTa₂O₆ or SrTiO₃; or a nitride such as SiNx or AlN. Of these, SiO₂, SiNx, Al₂O₃, Y₂O₃, Hf₂O₃ and CaHfO₃ are preferably used. More preferred are SiO₂, SiNx, Y₂O₃, Hf₂O₃ and CaHfO₃, and particularly preferred is Y₂O₃. The number of oxygen in these oxides is not necessarily agreed with the stoichiometric ratio (for instance, either SiO₂ or SiOₓ may be employed).

The gate insulator film 3 may have a layered structure in which two or more different insulator films are stacked. The gate insulator film 3 may be formed of any one of a crystalline substance, a polycrystalline substance or an amorphous substance. However, it is preferably formed of a polycrystalline substance or an amorphous substance because it is easy to produce industrially.

The insulator layer 3 may also be formed of an organic insulator such as parylene or polystyrene.

The second and third electrodes 4 and 5 are not particularly limited in the material, and various kinds of metals, metal oxides, carbon and organic conductive materials may be used. Specifically, platinum (Pt), gold (Au), silver (Ag) copper (Cu), aluminum (Al), a Mg—Ag alloy, a Li—Al alloy, calcium (Ca), indium-tin oxide (ITO), indium-zinc oxide, zinc-tin oxide, tin oxide, zinc oxide and titanium-niobium oxide are suitably used.

Next, the method of producing the semiconductor device of the invention will be explained.

In this embodiment, a Si substrate is used as the substrate 6, and as an insulator layer 3 is a SiO₂ thermally oxidized film obtained by thermally oxidizing the Si substrate 6. As the material for the oxide semiconductor layer 11, an oxide having n-type properties is used, and as the material for the organic semiconductor layer 10, an organic substance having p-type properties is used.

First, an insulator layer 3 is formed on a substrate 6, and second and third electrodes 4 and 5 are formed on the insulator layer 3 by the vacuum vapor deposition method. Next, an oxide semiconductor layer 11 is formed using a sputtering apparatus or the like, and placed in the presence of oxygen and/or ozone. Then, an organic substance is film-formed on the upper side of the oxide semiconductor layer 11 by the vacuum vapor deposition method.

According to the production method having such a constitution, after the oxide semiconductor layer 11 is formed, it can be exposed to an environment in the presence of oxygen such as in the air and subjected to washing or modification of the surface such as ozone treatment.

In the case of using an organic semiconductor layer having n-type properties, when the organic semiconductor layer is exposed to an environment in the present of oxygen and/or ozone, the properties typically deteriorate. Thus, the organic semiconductor layer has to be produced in the absence of oxygen such as in vacuo. In contradiction to this, like the invention, when an oxide semiconductor layer 11 having n-type properties is exposed to an environment in the presence of oxygen, it can be expected that polar functional groups such as —OH increase on the surface due to operation of oxygen or ozone so that injection properties of electrons and holes are changed.

Namely, an organic substance having p-type properties is used for the organic semiconductor layer 10 and an oxide having n-type properties is used for the oxide semiconductor layer 11 so that even if the oxide semiconductor layer 11 having n-type properties is exposed to atmosphere during the production, the properties do not deteriorate. By this, freedom of the production process is large and the practical application becomes easy.

When using this semiconductor device, the first electrode 2 is used as a gate electrode, and among the second electrode 4 and the third electrode 5, the one being higher in voltage is used as a hole-injecting electrode and the one being lower in voltage is used as an electron-injecting electrode.

Voltages applied to the first to third electrodes 2, 4 and 5, respectively are adjusted, and holes from the hole-injecting electrode are injected mainly to the organic semiconductor layer 10. Electrons from the electron-injecting electrode are injected mainly to the oxide semiconductor layer 11.

According to this manner, in the semiconductor device, electrons and holes recombine with each other within the light-emitting part 1 to generate energy due to the recombination. Organic substance molecules or oxide molecules residing in the vicinity of the portion where recombination occurred are exited from their ground states, and release energy which is the difference in energy between the excited state and the ground state, as light emission (electroluminescence) at the time when they return to the ground state.

Further, at this time, when holes and electrons recombine with each other in the vicinity of the organic semiconductor layer 10 or the interface between the organic semiconductor layer 10 and the oxide semiconductor layer 11, the organic substance molecules are exited, and light emission occurs from the organic substance molecules as mentioned above. By this, luminous efficiency becomes better.

Although recombination of holes and electrons may occur in the position other than the organic semiconductor layer 10 or the vicinity of the interface between the organic semiconductor layer 10 and the oxide semiconductor layer 11, the oxide semiconductor layer 11 is apt to lose the energy in a manner other than light emission, thereby luminous quantum efficiency decreasing. Further, a band gap is larger so that it is difficult to obtain light emission having a desired wavelength, therefore, luminous efficiency function also decreases.

For instance, electrical current flowing between the second electrode 4 and the third electrode 5 is controlled by fixing voltages applied to the first electrode 2 and the second electrode 4 and varying voltage applied to the third electrode 5, or fixing voltage applied to the second electrode 4 and the third electrode 5 and varying voltage applied to the first electrode 2.

By this manner, the amount of carriers (holes and electrons) injected to the light emitting part 1 increases or decreases.

By this, amount of carriers (holes and electrons) injected to the light emitting part 1 can be adjusted by adjusting voltages of the electrodes 2, 4 and 5, respectively, so that luminance can be controlled.

The semiconductor device comprises the organic semiconductor layer 10 and the oxide semiconductor layer 11 so that bipolar properties are stabilized. The light emitting part 1 is composed of an organic semiconductor layer 10 and the oxide semiconductor 11, and formed in combination of an organic substance and an oxide. Therefore, it becomes easy to appropriately determine balance of both carriers injected, thereby production yield becomes good. Thus, the production efficiency can be improved.

In the semiconductor device, an organic substance having p-type properties or bipolar-type properties and an oxide having n-type properties are used for the light emitting part 1. Therefore, electron carrier mobility stabilizes. Therefore, not only the luminous efficiency of the light emitting part 1 is enhanced but also it operates as a transistor. In particular, the transistor functions are good in an atmosphere, and it becomes easy for practical application.

In this embodiment, the field-effect mobility of the light emitting part 1 formed of semiconductors is usually 10⁻⁴ cm²/Vs or more. When the field-effect mobility is less than 10⁻⁴ cm²/Vs, switching speed may decrease or bipolar properties may not be exhibited. To avoid these problems more effectively, the filed-effect mobility is preferably 10⁻³ cm²/Vs or more, more preferably 10⁻² cm²/Vs or more, further preferably 10⁻¹ cm²/Vs or more and particularly preferably 1 cm²/Vs or more.

A ratio of field-effect mobility μ(n) at n-type driving and field-effect mobility μ(p) at p-type driving [μ(n)/μ(p)] is usually in a range of 10⁻⁵≦μ(n)/μ(p)≦10⁵, preferably in a range of 10⁻³≦μ(n)/μ(p)≦10⁴, more preferably in a range of 10⁻²≦μ(n)/μ(p)≦10³, and particularly preferably in a range of 10⁻¹≦μ(n)/μ(p)≦10². When the ratio μ(n)/μ(p) is outside the above-mentioned range, balance of n-type and p-type is disrupted so that expression of bipolar properties may be unclear.

A ratio W/L of a channel width, W, and a channel length, L is usually 0.1 to 100, preferably 1 to 20, and particularly preferably 2 to 8. When the ratio W/L exceeds 100, leakage current may increase, and an on-off ratio may decrease. When it is less than 0.1, the field-effect mobility may decrease, and pinch-off may be unclear.

The channel length, L, is usually 0.1 to 1000 μm, preferably 1 to 100 μm, and further preferably 2 to 10 μm. When it is 0.1 μm or less, the industrial production is difficult, and short channel effect may occur or leakage current may increase. When it is 1000 μm or more, the device is too large in size, it being undesirable.

Voltage applied to among electrodes during driving is usually 100 V or less, preferably 50 V or less, more preferably 20 V or less, and further preferably 10 V or less. When it is larger than 100 V, power consumption becomes larger so that usefulness may decrease.

Here, “to display bipolar properties” means the case where there exists drain voltage having a region where drain current increases by increasing gate voltage and a region where drain current increases by decreasing gate voltage.

### Second Embodiment

FIG. 2 is a schematic cross-sectional view of the semiconductor device according to the second embodiment of the invention.

The semiconductor device of this embodiment is almost the same as the above-mentioned embodiment but is different in the point where the substrate 6 and the first electrode 2 are formed separately.

Namely, in the semiconductor device of this embodiment, the first electrode 2 distinct from the substrate 6 is provided in the central part of the substrate 6. The first electrode 2 is formed of the material used for the second and third electrodes 4 and 5 in the above-mentioned first embodiment. The insulator layer 3 is provided on the substrate 6 and the first electrode 2.

The other constitutions are the same as the above-mentioned ones.

The semiconductor device of this embodiment is used as a tight-emitting element in the same as the above-mentioned embodiment. The operations and effects are almost the same as above.

According to the semiconductor device having such a constitution, leakage current can be reduced since overlapping between the first electrode 2 and the second and third electrodes 4 and 5 is small.

### Third Embodiment

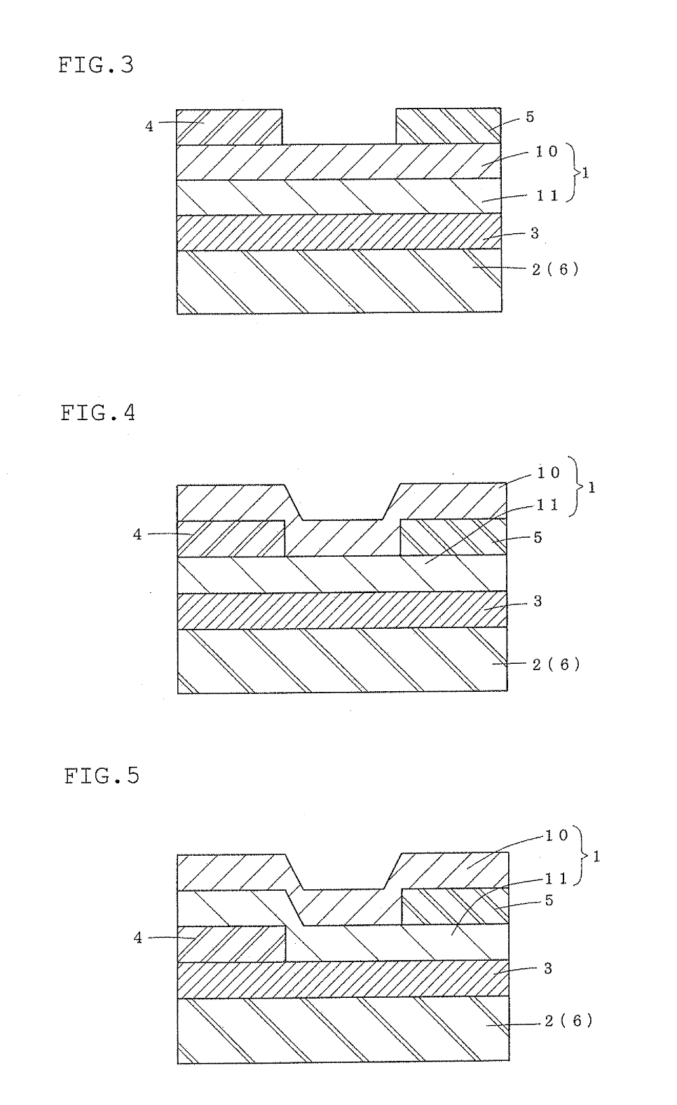

FIG. 3 is a schematic cross-sectional view of the semiconductor device according to the third embodiment of the invention.

The semiconductor device of this embodiment has the constitution, in which the second and third electrodes 4 and 5 are disposed on the upper side of the organic semiconductor layer 10 but not between the insulator layer 3 and the oxide semiconductor layer 11, and which is different from the above-mentioned embodiments.

According to the semiconductor layer having the constitution, mobility of the transistor can be adjusted to be high, since the electric field between the first electrode 2 and the second and third electrodes 4 and 5 is effectively applied to the oxide semiconductor layer 11 and the organic semiconductor layer 10.

### Fourth Embodiment

FIG. 4 is a schematic cross-sectional view of the semiconductor device according to the fourth embodiment of the invention.

The semiconductor device of this embodiment has the constitution in which the second and third electrodes 4 and 5 are disposed between the organic semiconductor layer 10 and the oxide semiconductor layer 11 but not between the insulator layer 3 and the oxide semiconductor layer 11, and which is different from the above-mentioned embodiments.

Mobility of the transistor can be adjusted to be high, since the electric field between the first electrode 2 and the second and third electrodes 4 and 5 is effectively applied to the oxide semiconductor layer 11. Further, it is no need to care that the organic semiconductor layer 10 is damaged during film formation of the second and third electrodes 5, since the oxide semiconductor layer 11 is formed thereafter.

### Fifth Embodiment

FIG. 5 is a schematic cross-sectional view of the semiconductor device according to the fifth embodiment of the invention.

The semiconductor device of this embodiment has the constitution in which the third electrode 5 is disposed between the organic semiconductor layer 10 and the oxide semiconductor layer 11 but not between the insulator layer 3 and the oxide semiconductor layer 11, and which is different from the above-mentioned embodiments.

Electrons and holes can efficiently recombine with each other so that luminous efficiency can be made to be higher, since there is the interface of the organic semiconductor layer 10 and the oxide semiconductor layer 11 between the second and third electrodes. Further, it is no need to care that the organic semiconductor layer 10 is damaged during film formation of the second and third electrodes 4 and 5, since the oxide semiconductor layer 11 is formed thereafter.

### Sixth Embodiment

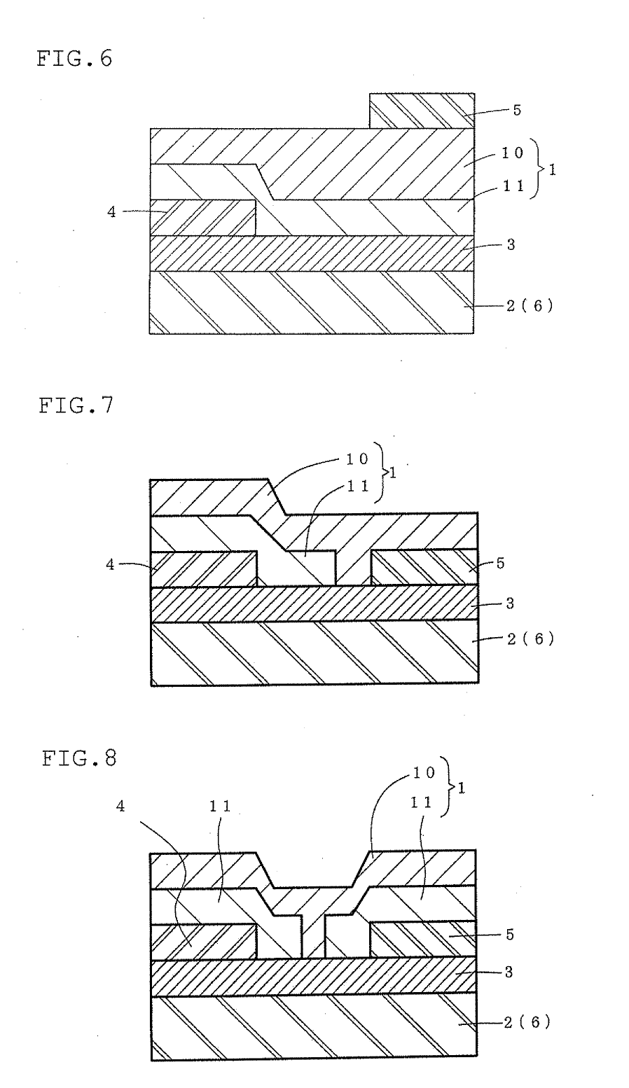

FIG. 6 is a schematic cross-sectional view of the semiconductor device according to the sixth embodiment of the invention.

The semiconductor device of this embodiment has the constitution in which the third electrode 5 is disposed on the upper side of the organic semiconductor layer 10 but not between the insulator layer 3 and the oxide semiconductor layer 11, and which is different from the constitution of the above-mentioned first embodiment.

Electrons and holes can efficiently recombine with each other so that luminous efficiency can be made to be higher, since there is the interface of the organic semiconductor layer 10 and the oxide semiconductor layer 11 between the second and third electrodes.

### Seventh Embodiment

FIG. 7 is a schematic cross-sectional view of the semiconductor device according to the seventh embodiment of the invention.

The semiconductor device of this embodiment has the constitution in which only the second electrode 4 is covered with the oxide semiconductor layer 11 and the organic semiconductor layer 10 covers the oxide semiconductor layer 11 and the third electrode 5, and which is different from the above-mentioned first embodiment.

Electrons and holes can efficiently recombine with each other so that luminous efficiency can be made to be higher, since there is the interface of the organic semiconductor layer 10 and the oxide semiconductor layer 11 between the second and third electrodes.

### Eighth Embodiment

FIG. 8 is a schematic cross-sectional view of the semiconductor device according to the eighth embodiment of the invention.

The semiconductor device of this embodiment has the constitution in which part of the organic semiconductor layer 10 runs down to the insulator layer 3 side between the second electrode 4 and the third electrode 5, and which is different from the above-mentioned first embodiment. Further, it has the constitution in which the part running down separates the oxide semiconductor layer 11 to the second electrode 4 side and the third electrode 5 side.

Electrons and holes can efficiently recombine with each other so that luminous efficiency can be made to be higher, since there is the interface of the organic semiconductor layer 10 and the oxide semiconductor layer 11 between the second electrode 4 and the third electrode 5.

According to the constitutions of the semiconductor devices of the third to eighth embodiments, the second and third electrodes 4 and 5 may be disposed relative to the organic semiconductor layer 10 and the oxide semiconductor layer 11 in the light-emitting part 1 in the above-mentioned manners. Therefore, freedom of circuit design using the semiconductor device can be increased.

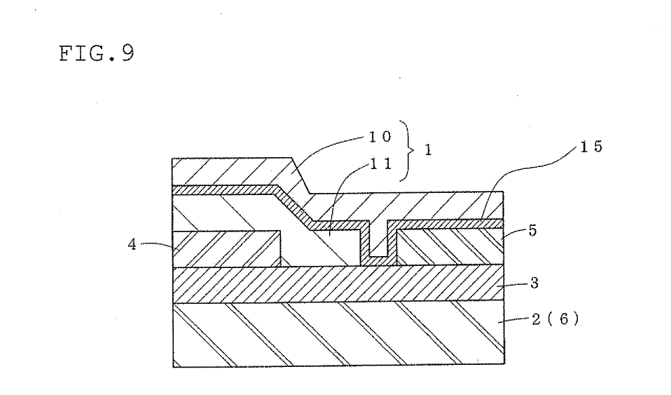

Further, in the semiconductor devices according to the above-mentioned embodiments, the multilayer technique used in the field of organic EL devices may be used. For instance, as shown in FIG. 9, an organic light-emitting layer 15 is disposed between the organic semiconductor layer 10 and the oxide semiconductor layer 11, and light emission is caused in the layer 15, etc. This constitution is preferable, since luminous efficiency can be increased and wave length of light to be emitted can be adjusted.

Furthermore, in the semiconductor device according to the above-mentioned embodiment, energy transmission between the organic semiconductor layer 10 and the oxide semiconductor layer 11 is limited by providing a protective layer between the organic semiconductor layer 10 and the oxide semiconductor layer 11, by modifying the surface of the oxide semiconductor layer 11, or the like, so that quenching can preferably be prevented.

In the semiconductor device according to the above-mentioned embodiments, other various technologies used in the organic EL field can be applied freely. Such technologies are described in “Organic EL display”, by Ohmsha, Ltd. issued on Aug. 20, 2004, for example.

### [Display Apparatus]

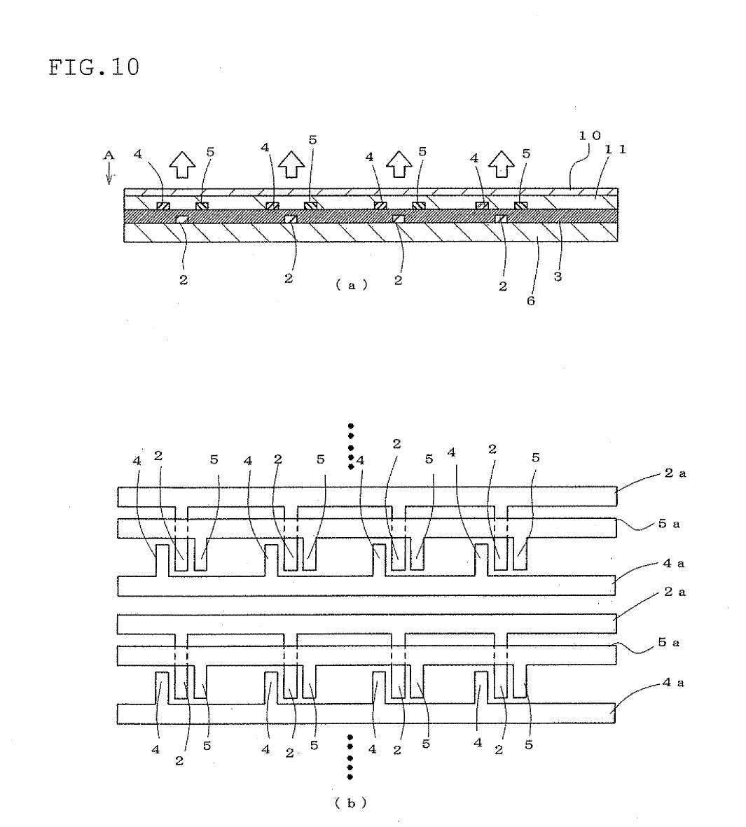

The semiconductor devices of the first to eighth embodiments are used for a display apparatus as shown in FIG. 10, for example.

In the display apparatus of this embodiment, a plurality of the semiconductor devices of the second embodiment are aligned in lines in the direction of the plane of the substrate, as shown in FIGS. 10(a) and 10(b).

The organic semiconductor layer 10, the oxide semiconductor layer 11 and the substrate 6 are formed together over the entire surface.

Also, as shown in FIG. 10(b), the first electrodes 2 of the semiconductor device, which align in row, are connected to each other through a conductor 2a. The second and third electrodes 4 and 5 of the semiconductor device, which align in row, are also connected to each other through conductors 4a,5a in the same manner as in the first electrode 2.

The light-emitting part emits light (L) by varying the voltage to be applied to the third electrode 5 while fixing the voltages to be applied to the first electrode 2 and the second electrode 4, or by varying the voltage to be applied to the first electrode 2 (gate voltage) while fixing the voltages to be applied to the second electrode 4 and the third electrode 5.

By using the semiconductor device having light-emitting function and transistor function, structure of the display apparatus is simple. By this, the production process of the display apparatus is simple so that production efficiency can be increased.

In addition to the above-mentioned embodiments, the semiconductor device can be freely applied by replacing n-type organic semiconductor with n-type oxide semiconductor in various light-emitting systems, colorization methods, structures of a panel, production processes, etc. such as function-integrated light-emitting transistor, PN-junction function-separated light-emitting transistor, static induction transistor, metal-base organic transistor, RGB independent system and color filter system (CF). These various light-emitting systems, colorization methods, structures of a panel, production processes, etc. are described in “Production processes for organic light-emitting transistor commentated with reference to pictures, 2006 version” issued by E Express Inc.

### Example 1

### Top Contact

As shown in FIG. 3, a semiconductor device according to this example was produced in the following manner:

First, a conductive Si substrate was used as a substrate 6, and subjected to heat-oxidization to form an insulator layer 3. Next, an oxide semiconductor layer 11 was formed using sputtering equipment. The film-forming conditions were as follows: In₂O₃—ZnO (an oxide composed of In=93 at % and Zn=7 at % in the elemental ratio; IZO (registered trademark)) was used as a target, ultimate vacuum: 8.2×10⁻⁴ Pa, sputtering vacuum: 1.9×10⁻¹ Pa, sputtering gas: Ar 32 sccm, sputtering power: 50 W, and no substrate heating was conducted. After sputter deposition, heat treatment at 300° C. for one hour under atmosphere was conducted. UV ozone treatment was conducted for 15 minutes while exposing to atmosphere, and then, tetracene was deposited on the top surface of the oxide semiconductor layer 11 by the vacuum deposition method.

Then, Au was deposited through a metal mask by the vacuum deposition method to form a film, and two electrodes 4 and 5 of second and third electrodes were formed.

The semiconductor device produced in the above-mentioned manner had the following constitutions: Si/SiO₂ film: 300 nm (the substrate (the first electrode) and the insulator layer), Au film: 50 nm (the second and third electrodes), In₂O₃—ZnO film (polycrystalline): 5 nm (the oxide semiconductor layer 11), tetracene film: 50 nm (the organic semiconductor layer 10), channel length L (distance between the second electrode 4 and the third electrode 5): 200 μm. Channel width W was 2 mm.

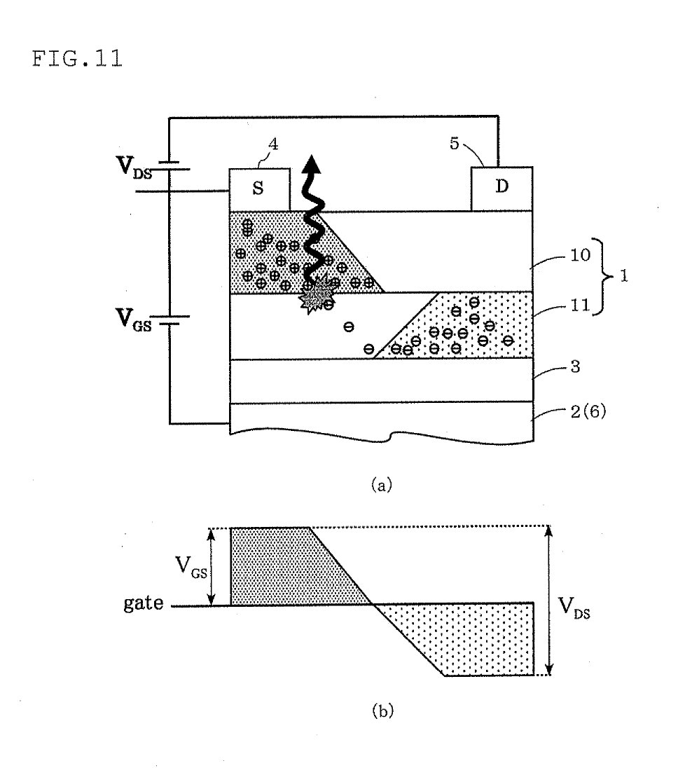

The semiconductor device of this example was wired as shown in FIGS. 11A and 11B. The first electrode 2 was made to a gate electrode, the second electrode 4 was made to a source electrode (hole injecting electrode), and the third electrode 5 was made to a drain electrode (electron injecting electrode).

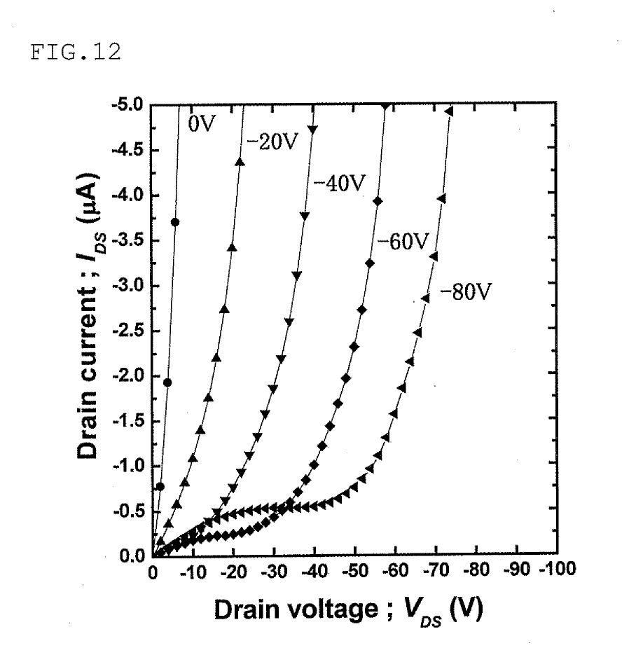

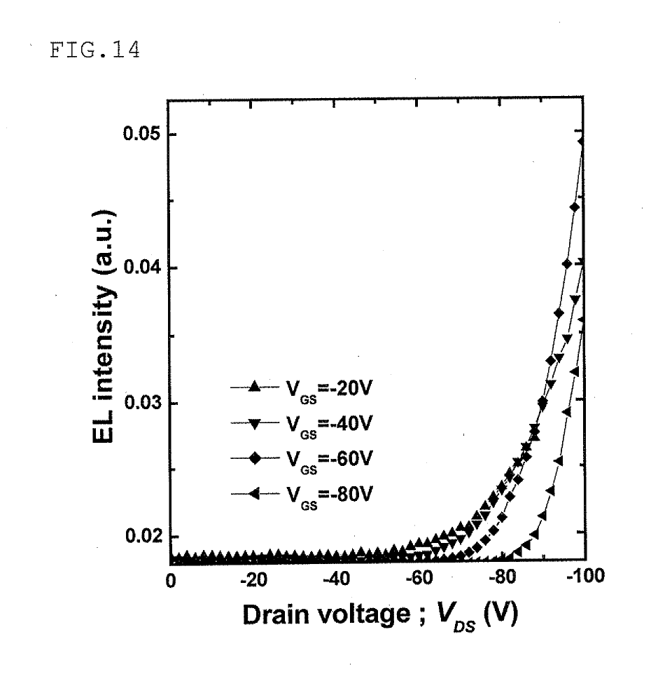

FIGS. 12 to 16 show the transistor characteristics and emission properties of this semiconductor device.

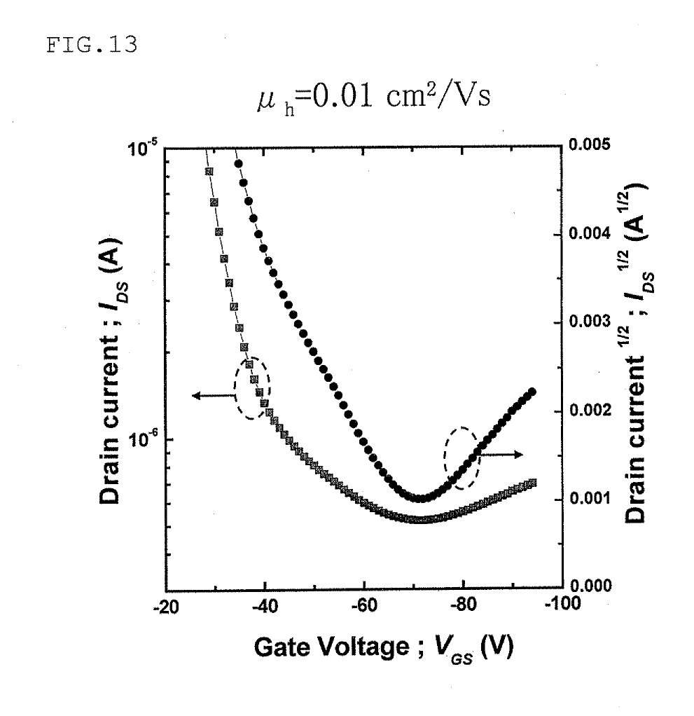

According to this semiconductor device, luminance can be controlled by gate voltage or drain voltage (FIGS. 11 and 12). It can be found that this semiconductor device displays bipolar properties (FIG. 13).

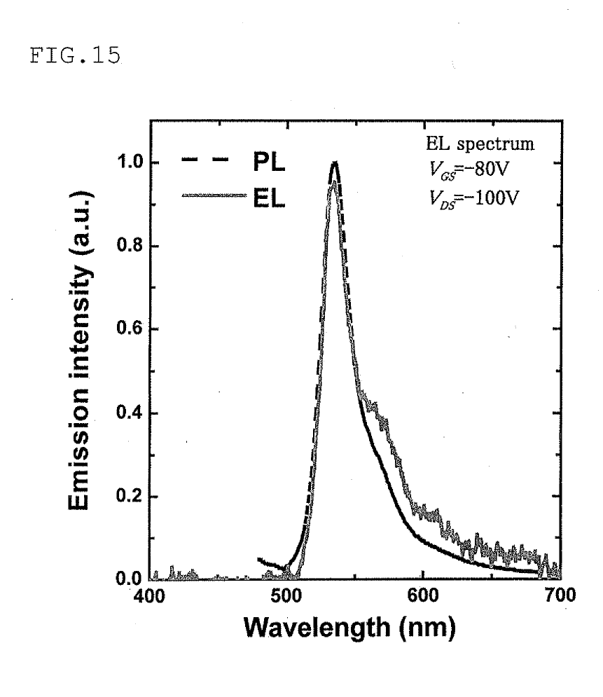

The EL (electroluminescence) spectrum of the semiconductor device of this example and the PL (photoluminescence) spectrum of tetracene significantly agree to each other (FIG. 15). From this fact, it is considered that in this device, electrons are injected from the In₂O₃—ZnO film to the tetracene film, and recombination occurs in the tetracene film to emit light.

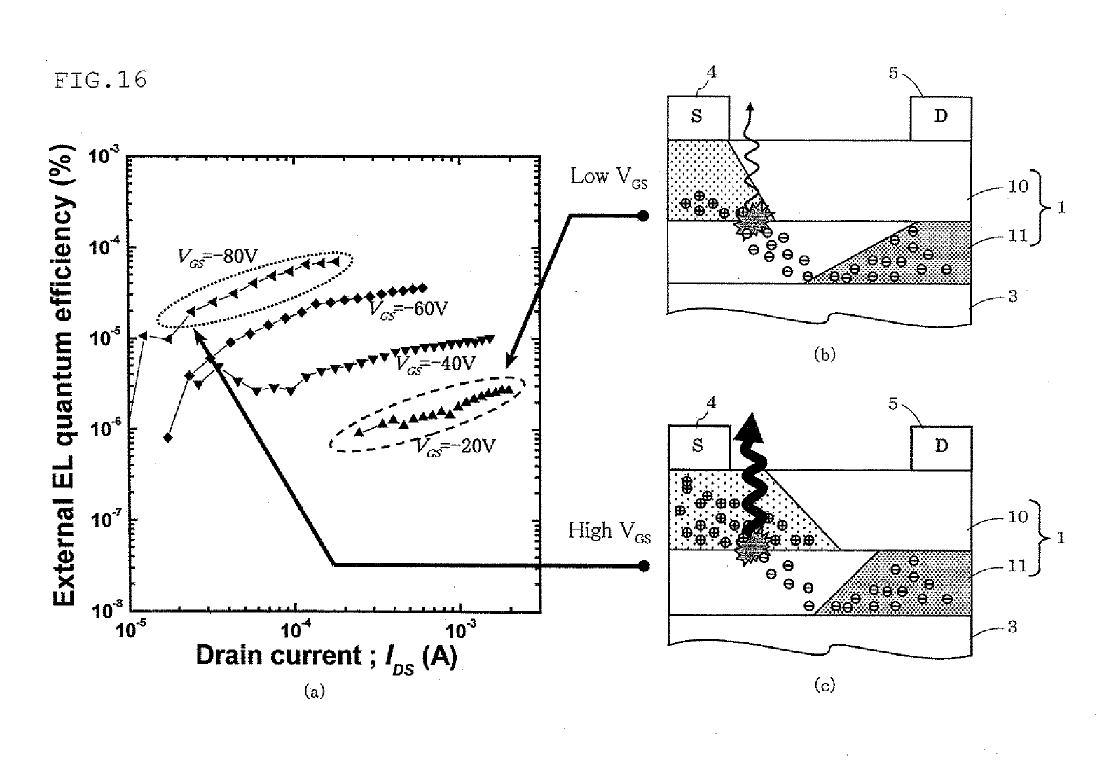

As the gate voltage increases, increase of the EL external quantum efficiency was observed (FIG. 16(a)). This fact is considered as follows: When the gate voltage is low, amount of holes injected to the organic semiconductor layer 10 is small (FIG. 16 (b)). However, when increasing the gate voltage, amount of holes injected to the organic semiconductor layer 10 becomes larger (FIG. 16(c)).

Namely, according to this semiconductor device, amount of carrier injected to the light-emitting part 1 can be increased or decreased by changing the gate voltage or the drain voltage, to control luminance.

### Example 2

### Bottom Contact

As shown in FIG. 1, a semiconductor device according to this example was produced as follows:

First, a conductive Si substrate was used as a substrate 6, and subjected to heat-oxidation to form an insulator layer 3. Next, a positive type photoresist was applied on the insulator layer 3 by spin coating. The photoresist was pre-baked at a predetermined temperature to become solidified, and the central part of the substrate 6 was exposed. Then, the photoresist other than the central part of the substrate 6 was removed using a rinse liquid, and the rinse liquid no longer in use was vaporized and removed by post-baking. Then, Cr and Au were deposited on this substrate 6 by the vacuum deposition method to form films, and the films were subjected to liftoff using a solvent to form two electrodes 4 and 5 of second and third electrodes in the part other than the central part of the substrate 6.

Next, an oxide semiconductor layer 11 was formed on the substrate 6 on which the second and third electrodes 4 and 5 were provided using sputtering equipment. The film-forming conditions were as follows: In₂O₃—ZnO (an oxide composed of In=93 at % and Zn=7 at % in the elemental ratio) was used as a target, ultimate vacuum: 8.2×10⁻⁴ Pa, sputtering vacuum: 1.9×10⁻¹ Pa, sputtering gas: Ar 10 sccm and O₂ 1 sccm, sputtering power: 50 W, and no substrate heating was conducted. After sputter deposition, heat treatment at 300° C. for one hour under atmosphere was conducted. UV ozone treatment was conducted for 15 minutes while exposing to atmosphere, and then, 1,4-bis(4-methylstyryl)benzene (4MSB) was deposited on the top surface of the oxide semiconductor layer 11 by the vacuum deposition method.

Fluorescence quantum yield of 4MSB was about 40%.

The semiconductor device produced in the above-mentioned manner had the following constitutions: Si/SiO₂ film: 300 nm (the substrate (the first electrode) and the insulator layer), Cr film: 1 nm, Au film: 39 nm (the second and third electrodes), In₂O₃—ZnO film (polycrystalline): 1.5 nm (the oxide semiconductor layer 11), 4MSB film: 50 nm (the organic semiconductor layer 10), channel length L (distance between the second electrode 4 and the third electrode 5): 25 μm. Channel width W was 4 mm.

In the semiconductor device of this example, the first electrode was made to a gate electrode, the second electrode was made to a source electrode, and the third electrode was made to a drain electrode in the same manner as in the example above.

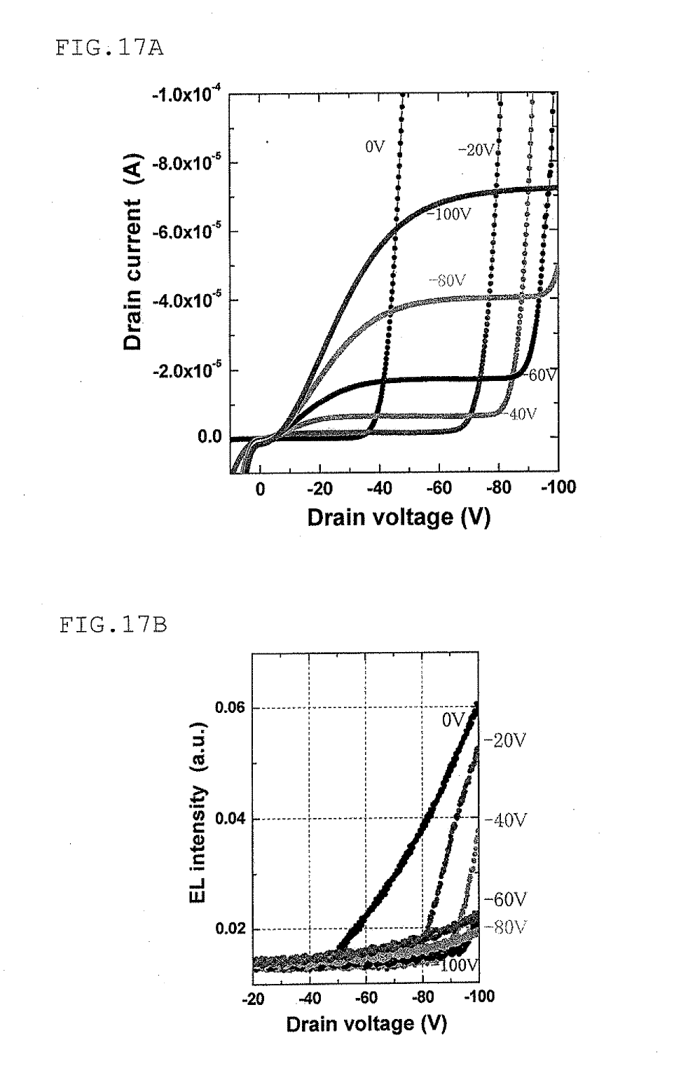

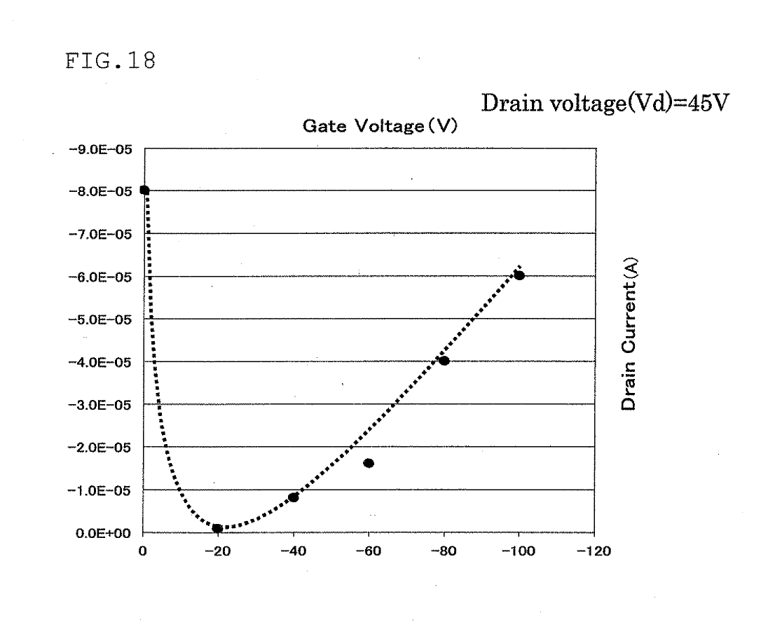

FIGS. 17A, 178 and 18 shows the transistor characteristics and emission properties of this semiconductor device. According to this semiconductor device, luminance can be controlled by gate voltage or drain voltage (FIG. 17B). It can be found that this semiconductor device displays bipolar properties (FIG. 18).

### Comparative Example 1

A semiconductor device was produced in the same manner as in Examples 1 and 2 except that no oxide semiconductor layer was provided. The semiconductor device indicated the transistor characteristics but not display the bipolar characteristics and emission properties.

Hereinbefore, the semiconductor device, the method of producing the semiconductor device and the display apparatus of the invention are explained with showing the preferred embodiments. However, it should be noted that the device according to the invention be not limited only to the above-mentioned embodiments, and various modifications could be possible within the scope of the invention.

For instance, the display apparatus having the constitution in which the semiconductor devices of the second embodiment are lined up is shown. However, it is not limited to this constitution, and the above-mentioned semiconductor device of the other embodiments may be used or the constitution may be changed optionally.

1. A semiconductor device which comprises an organic semiconductor layer and an oxide semiconductor layer, and emits light.

2. The semiconductor device according to claim 1, wherein the light emitted is generated by recombination of holes and electrons.

3. The semiconductor device according to claim 1, which is a transistor displaying bipolar properties of n-type and p-type.

4. The semiconductor device according to claim 1, wherein the oxide semiconductor layer is made of an n-type nondegenerate oxide and has an electron carrier concentration of less than 10¹⁸/cm³.

5. The semiconductor device according to claim 1, wherein the oxide semiconductor layer is formed of an amorphous oxide containing at least one selected from In, Zn, Sn and Ga.

6. The semiconductor device according to claim 5, wherein the oxide semiconductor layer is formed of an amorphous oxide containing In, Ga and Zn, an amorphous oxide containing Sn, Zn and Ga, an amorphous oxide containing In and Zn, an amorphous oxide containing In and Sn, an amorphous oxide containing In and Ga, or an amorphous oxide containing Zn and Sn.

7. The semiconductor device according to claim 1, wherein the oxide semiconductor layer is formed of a polycrystalline oxide containing In, Zn, Sn or Ga.

8. The semiconductor device according to claim 7, wherein the oxide semiconductor layer is formed of a polycrystalline oxide containing In and a positive divalent element.

9. The semiconductor device according to claim 1, wherein the oxide semiconductor layer has a multilayered structure in which plural kinds of layered oxides are stacked, and among said multilayered structure, the material of the layered oxide layer nearest to the organic layer has the work function larger than the work function of the other layered oxide.

10. The semiconductor device according to claim 1, wherein the organic semiconductor layer is formed of an organic substance having p-type characteristics, an organic substance having bipolar properties or an organic substance having n-type properties; or a multilayered body or a mixture of two or more kinds thereof.

11. The semiconductor device according to claim 1, wherein the organic semiconductor layer is formed from an organic substance which emits light due to recombination of holes and electrons.

12. The semiconductor device according to claim 1, wherein the organic semiconductor layer and the oxide semiconductor layer are in contact with each other.

13. The semiconductor device according to claim 1, wherein the organic semiconductor layer and the oxide semiconductor layer form a light-emitting part.

14. The semiconductor device according to claim 13, wherein a first electrode is provided on the light-emitting part through an insulator layer, a second electrode is provided in contact with the light-emitting part and interspatially from said first electrode, and a third electrode is provided in contact with the light-emitting part and interspatially from said first and second electrodes.

15. The semiconductor device according to claim 14, wherein the organic semiconductor layer and the oxide semiconductor layer are formed into a thin film.

16. The semiconductor device according to claim 13, wherein a ratio of field-effect mobility μ(n) at n-type driving and field-effect mobility μ(p) at p-type driving [μ(n)/μ(p)] is in a range of 10⁻⁵≦μ(n)/μ(p)≦10⁵.

17. A method of producing the semiconductor device according to claim 1, wherein an oxide semiconductor layer is formed, said oxide semiconductor layer is placed in the presence of oxygen and/or ozone, and then an organic semiconductor layer is formed.

18. A display apparatus using the semiconductor device according to claim 1.
